(19) United States
(12) Patent Application Publication
(10) Pub. No.: US 2023/0276607 A1
(43) Pub. Date: Aug. 31, 2023

(54) COMPONENT MOUNTING SYSTEM AND METHOD FOR SUPPLYING ELECTRONIC COMPONENT

(71) Applicant: FUJI CORPORATION, Chiryu (JP)

(72) Inventor: Takeshi SAKURAYAMA, Nisshin-shi (JP)

(73) Assignee: FUJI CORPORATION, Chiryu (JP)

(21) Appl. No.: 18/006,618

(22) PCT Filed: Aug. 26, 2020
(86) PCT No.: PCT/JP2020/032116

§ 371 Date: Jan. 24, 2023

(51) Int. Cl. H05K 13/04

(52) U.S. Cl. CPC H05K 13/0419; H05K 13/0452

(57) ABSTRACT

A component mounting system includes: a tape-type component supply feeder detachably attached to a component mounting machine for mounting an electronic component on a board, having a component feeding mechanism feeding out the electronic component to be accommodated in a tape to a supply position, and configured to supply the electronic component fed to the supply position to the component mounting machine; a storage section configured to store shape data of the electronic component; and a control section configured to determine a speed from a time when the electronic component is fed to the supply position to a time when the electronic component is stopped by the component feeding mechanism, based on the shape data of the electronic component.

### TECHNICAL FIELD

A technology disclosed in the present specification relates to a component mounting system for mounting an electronic component on a board and a method for supplying the electronic component to a component mounting machine.

### BACKGROUND ART

In a component mounting machine for mounting an electronic component on a board, a component supply feeder is detachably attached to the component mounting machine, and electronic components are supplied from the component supply feeder. As the component supply feeder, for example, a tape-type component supply feeder in which multiple electronic components are accommodated in a tape and supplying the electronic components by feeding the tape to a supply position is known. In the tape-type component supply feeder, conditions such as a speed and an acceleration at which the electronic component is fed (hereinafter, also referred to as a supply condition) are set so that the electronic component is supplied to the supply position at regular time intervals. Appropriate supply conditions may differ depending on the type of electronic component. For example, in a tape-type component supply feeder, a magnet is disposed below the tape, and as for an electronic component having magnetism, the deviation of the electronic component (for example, a protrusion from a cavity provided in the tape for accommodating the electronic component) is prevented when the electronic component is fed out by the magnet. On the other hand, in an electronic component having no magnetism, the electronic component cannot be made difficult to deviate by the magnet. Therefore, for example, in a component mounting machine disclosed in JP-A-2019-096664, it is determined whether an electronic component has magnetism, and when supplying an electronic component having no magnetism, the supply condition is changed such that the feeding speed is reduced. As a result, electronic components that do not have magnetism are also made difficult to deviate when being supplied.

### BRIEF SUMMARY

### Technical Problem

In the component mounting machine described in JP-A-2019-096664, the supply condition is changed such that the speed at which the electronic component is fed out is reduced according to the presence or absence of magnetism of the electronic component. However, the deviation of the electronic component at the time of feeding out may be affected not only by the presence or absence of magnetism of the electronic component but also by the shape of the electronic component. Determining what kind of shape an electronic component is likely to deviate when it is fed out depends on the experience and skill of the operator.

The present specification discloses a technology for facilitating normal supply of electronic components supplied from the component supply feeder.

### Solution to Problem

The component mounting system disclosed in the present specification includes a tape-type component supply feeder detachably attached to a component mounting machine for mounting an electronic component on a board, having a component feeding mechanism feeding out the electronic component to be accommodated in a tape to a supply position, and configured to supply the electronic component fed to the supply position to the component mounting machine, a storage section configured to store shape data of the electronic component, and a control section configured to determine a speed from a time when the electronic component is fed to the supply position to a time when the electronic component is stopped by the component feeding mechanism, based on the shape data of the electronic component.

In addition, the component mounting system disclosed in the present specification includes a tape-type component supply feeder detachably attached to a component mounting machine for mounting an electronic component on a board, having a component feeding mechanism feeding out the electronic component to be accommodated in a tape to a supply position, and configured to supply the electronic component fed to the supply position to the component mounting machine, a storage section configured to store shape data of the electronic component, and a control section configured to determine an acceleration from a time when the electronic component is fed to the supply position to a time when the electronic component is stopped by the component feeding mechanism, based on the shape data of the electronic component.

In the component mounting system described above, the speed or acceleration when the component feeding mechanism feeds out the electronic component to the supply position is determined based on the shape data of the electronic component. As a result, the speed or acceleration at which the electronic component is fed out can be determined in accordance with the shape of the electronic component, so that the electronic component can be made difficult to deviate when it is supplied. Therefore, it is possible to appropriately supply the electronic component in accordance with the shape of the electronic component.

In addition, a supply method disclosed in the present specification is a method of supplying an electronic component to a supply position from a tape-type component supply feeder that is detachably attached to a component mounting machine that mounts the electronic component on a board and feeds out the electronic component accommodated in a tape to supply the electronic component to the component mounting machine The supply method includes a determining step of determining a speed from a time when the electronic component is fed to the supply position to a time when the electronic component is stopped based on shape data of the electronic component to be supplied, and a supplying step of supplying the electronic component based on the speed determined in the determining step.

In addition, a supply method disclosed in the present specification is a method of supplying an electronic component to a supply position from a tape-type component supply feeder that is detachably attached to a component mounting machine that mounts the electronic component on a board and feeds out the electronic component accommodated in a tape to supply the electronic component to the component mounting machine The supply method includes a determining step of determining an acceleration from a time when the electronic component is fed to the supply position to a time when the electronic component is stopped based on shape data of the electronic component to be supplied, and a supplying step of supplying the electronic component based on the acceleration determined in the determining step.

In the supply method described above, the speed or the acceleration when the electronic component is fed to the supply position is determined based on the shape data of the electronic component. Therefore, it is possible to provide the same operation and effect as those of the component supplying system described above.

### BRIEF DESCRIPTION OF DRAWINGS

FIG. 1 is a diagram illustrating a schematic configuration of a component mounting line included in a component mounting system according to an embodiment.

FIG. 2 is a diagram illustrating a schematic configuration of a component mounting machine.

FIG. 3 is a sectional view taken along a line of FIG. 2.

FIG. 4 is a diagram illustrating a schematic configuration of a component supply feeder.

FIG. 5 is a block diagram illustrating a control system of the component mounting machine.

FIG. 6 is an example of a schematic diagram illustrating an electronic component including leads, (a) is top view of the electronic component, and (b) is a side view illustrating a state in which the electronic component is accommodated in a base tape.

FIG. 7 is an example of a schematic diagram illustrating a thin electronic component, and illustrates a state in which the electronic component deviates from a cavity provided in the base tape.

FIG. 8 is a flowchart illustrating an example of processing for setting a tape supply condition when a tape feed-out mechanism supplies electronic components.

### DESCRIPTION OF EMBODIMENTS

Main features of embodiments described below are listed below. Technical elements described below are independent technical elements, exhibit technical usefulness alone or by various combinations, and are not limited to combinations described in the claims at the time of filing.

In a component mounting system disclosed in the present specification, when in an electronic component to be supplied, shape data of the electronic component stored in a storage section has a specific feature, a control section may determine a speed or an acceleration from when the electronic component is fed to the supply position to when the electronic component stops, so as to be smaller than the speed or the acceleration from when the other electronic component having no specific feature is fed to the supply position to when the electronic component stops. According to such a configuration, the speed or the acceleration at the time of supplying the electronic component is reduced for a component having a shape having a specific feature. As a result, for example, an electronic component having a shape with a specific feature that is likely to move when being supplied has a lower speed or acceleration when being supplied, whereas a component that does not have a shape with a specific feature does not have a lower speed or acceleration when being supplied. Therefore, it is possible to appropriately supply the electronic component in accordance with the shape of the electronic component.

The component mounting system disclosed in the present specification may further include a nozzle that picks up the electronic component at the supply position. The control section may determine whether the shape data of the electronic component stored in the storage section has a specific feature when a suction rate when the nozzle picks up the same type of electronic component multiple times is lower than a predetermined value. According to such a configuration, the control section determines whether the shape data of the electronic component having a low suction rate has a specific feature. As a result, for the electronic component having a low suction rate, by determining whether the shape data thereof has a specific feature, it is possible to specify a cause of the low suction rate (the shape data has a specific feature), and increases the suction rate of the electronic component.

The component mounting system disclosed in the present specification may further include a notification section for notifying that the determination to reduce the speed or the acceleration is made. According to such a configuration, it is possible to notify the operator that an absolute value of the acceleration at the time when the electronic component is fed to the supply position and is stopped is reduced.

In the component mounting system disclosed in the present specification, a specific feature may be a feature in which an electronic component includes leads extending from a main body of the electronic component when the electronic component is viewed in plan. According to such a configuration, it is possible to reduce the absolute value of the acceleration when the electronic component having a shape that easily deviates during supply is stopped at the supply position.

In the component mounting system disclosed in the present specification, a specific feature may be a feature in which a thickness of the electronic component is equal to or less than a predetermined thickness. According to such a configuration, it is possible to reduce the absolute value of the acceleration when the electronic component having a shape that easily deviates during supply is stopped at the supply position.

### Embodiment

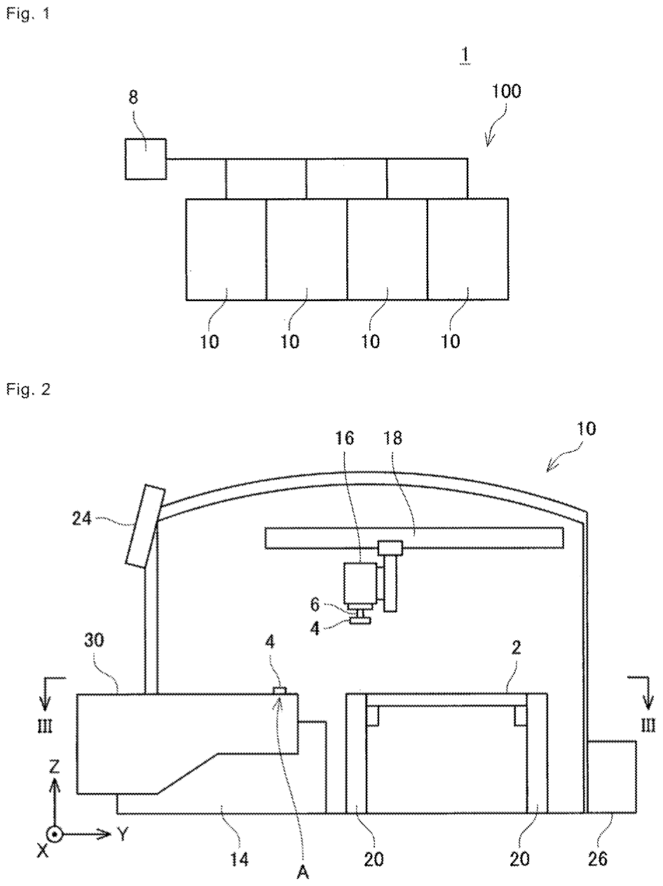

Component mounting system 1 of an embodiment will be described with reference to the drawings. As illustrated in FIG. 1, component mounting system 1 includes component mounting machine 10 and management device 8.

Component mounting machine 10 is communicably connected to management device 8. Management device 8 is communicably connected to multiple component mounting machines 10, and manages multiple component mounting machines 10. Management device 8 and multiple component mounting machines 10 constitute component mounting line 100. Management device 8 is configured using a computer including a CPU and a storage device. Management device 8 controls entire component mounting line 100 by controlling the operation of each component mounting machine 10. That is, management device 8 determines, for each of multiple component mounting machines 10, the type, position, and the like of electronic component 4 to be mounted on circuit board 2 by component mounting machine 10, and instructs component mounting machine 10 to do so. When component mounting machine 10 operates based on the instruction from management device 8, electronic components 4 necessary for circuit board 2 are mounted on circuit board 2. [0020] Component mounting machine 10 mounts electronic components 4 on circuit board 2. Circuit board 2 is sent from a first end of component mounting line 100 toward a second end. In each component mounting machine 10, electronic components 4 determined in advance are mounted to circuit board 2. Circuit board 2 sent to the second end of component mounting line 100 is shipped as a final product or is sent to a later step as a semi-finished product. Multiple component supply feeders 30 can be installed in component mounting machine 10. By installing component supply feeder 30 in component mounting machine 10, electronic component 4 is supplied from component supply feeder 30 to component mounting machine 10. In component mounting line 100, it is possible to install component supply feeder 30 on any of multiple component mounting machines 10. Which type of component supply feeder 30 is installed on component mounting machine 10 is determined in management device 8.

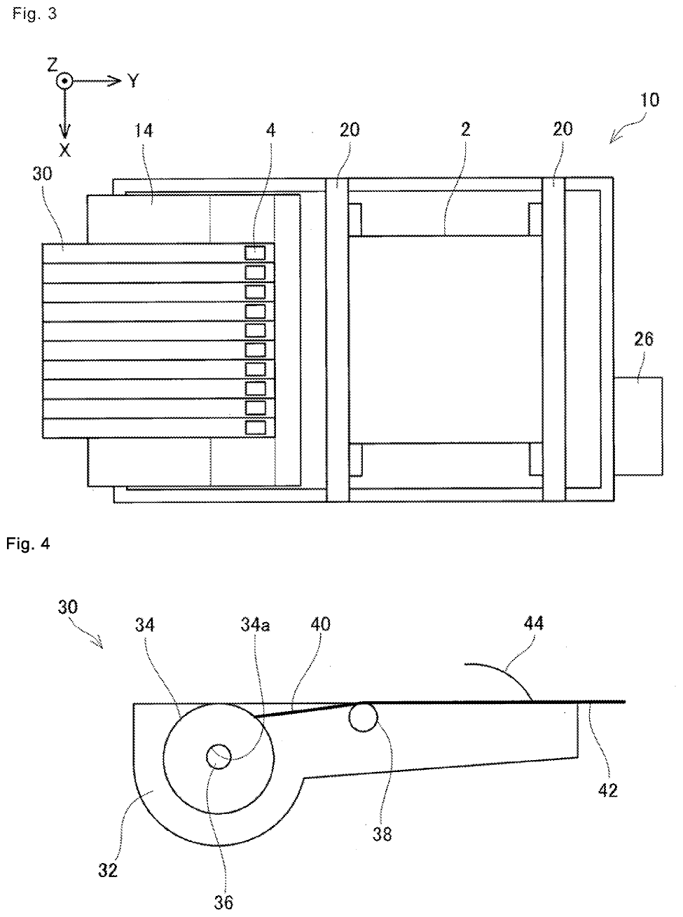

As illustrated in FIGS. 2 and 3, component mounting machine 10 includes multiple component supply feeders 30, feeder holding section 14, mounting head 16, head moving device 18, board conveyor 20, touch panel 24, and control device 26. Each component supply feeder 30 accommodates multiple electronic components 4. Component supply feeder 30 is detachably attached to feeder holding section 14 and supplies electronic components 4 to mounting head 16. A specific configuration of component supply feeder 30 will be described in detail later.

Feeder holding section 14 includes multiple slots, and it is possible to detachably install component supply feeder 30 in each of the multiple slots. Feeder holding section 14 may be fixed to component mounting machine 10 or may be detachably attached to component mounting machine 10. Mounting head 16 detachably holds one or multiple suction nozzles 6, uses suction nozzle 6 to pick up electronic component 4 supplied by component supply feeder 30, and mounts electronic component 4 on circuit board 2. At this time, head moving device 18 moves mounting head 16 with respect to component supply feeder 30 and circuit board 2. Accordingly, electronic component 4 is picked up from specific component supply feeder 30 of multiple component supply feeders 30, and electronic component 4 is mounted on circuit board 2 at a position determined in advance. Board conveyor 20 conveys in, supports, and conveys out circuit board 2. Touch panel 24 is a display device that provides an operator with various information of component mounting machine 10, as well as an input device that receives instructions or information from the operator. Control device 26 is configured using a computer including a CPU and a storage device. Control device 26 controls the operation of each section of component mounting machine 10 based on a production program transmitted from management device 8.

Component supply feeder 30 will be described with reference to FIG. 4. As illustrated in FIG. 4, component supply feeder 30 includes housing 32, reel 34, reel support portion 36, and tape feed-out mechanism 38.

Long tape 40 for accommodating multiple electronic components 4 at regular intervals is wound on reel 34. Tape 40 has base tape 42 and cover tape 44, and electronic component 4 is accommodated between base tape 42 and cover tape 44. Opening portion 34a is provided at the center of reel 34, and opening portion 34a is made larger than a dimension of reel support portion 36 (to be described later) in a radial direction. By inserting and engaging reel support portion 36 in opening portion 34a, reel 34 is installed in component supply feeder 30. Reel 34 is exchangeable with component supply feeder 30.

Reel support portion 36 is cylindrical, and a first end of reel support portion 36 is attached to housing 32. Reel support portion 36 rotatably supports reel 34.

Tape feed-out mechanism 38 feeds out tape 40 wound on reel 34 supported by reel support portion 36 by a constant amount from reel 34. The feeding amount of tape 40 by tape feed-out mechanism 38 is set according to the interval between electronic components 4 accommodated in tape 40. Cover tape 44 of fed tape 40 is peeled off at a position closer to reel 34 than a predetermined pick-up position (that is, supply position) A (refer to FIG. 2). When cover tape 44 is peeled off, electronic component 4 accommodated in tape 40 is exposed and is picked up by mounting head 16 at pick-up position A. Peeled cover tape 44 is fed to a discard position by a cover tape feeding mechanism (not illustrated). Conditions such as speed and acceleration for feeding tape 40 (for example, electronic component 4 accommodated in tape 40) by tape feed-out mechanism 38 (hereinafter, also referred to as a supply condition of tape 40) can be changed depending on the type of electronic component 4 accommodated in tape 40. The setting of the supply condition of tape 40 will be described in detail later.

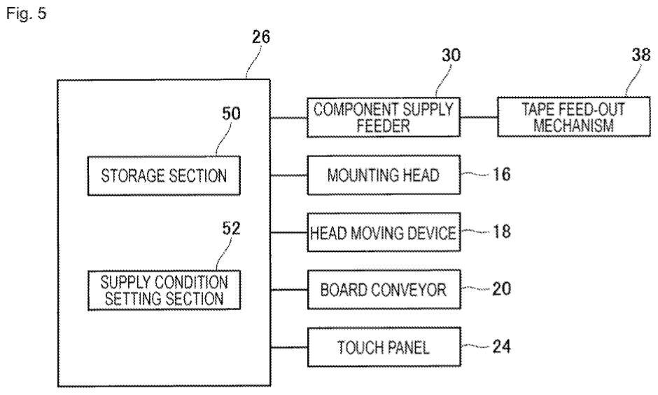

As illustrated in FIG. 5, control device 26 is connected to component supply feeder 30, mounting head 16, head moving device 18, board conveyor 20, and touch panel 24, and controls each section of component supply feeder 30, mounting head 16, head moving device 18, board conveyor 20, and touch panel 24. In addition, control device 26 also controls tape feed-out mechanism 38 included in component supply feeder 30. Tape feed-out mechanism 38 may be controlled by a control section (not illustrated) of component supply feeder 30.

In addition, control device 26 includes storage section 50 and supply condition setting section 52. Storage section 50 stores shape data of each electronic component 4. The shape data is stored in management device 8, and control device 26 acquires the shape data from management device 8, and stores the acquired shape data in storage section 50. The shape data includes, for example, information as to the outer shape of electronic component 4 and information as to constituent elements included in electronic component 4. Examples of the information as to the outer shape of electronic component 4 include a shape (for example, a rectangular shape or the like) as viewed in plan, the presence of the lead, the presence of the bump, a thickness of electronic component 4, and the like. Examples of the information as to the constituent elements included in electronic component 4 include the position of the lead in a case where the lead is provided (for example, the disposition position of the lead from the center of electronic component 4), the number of the leads, and the like.

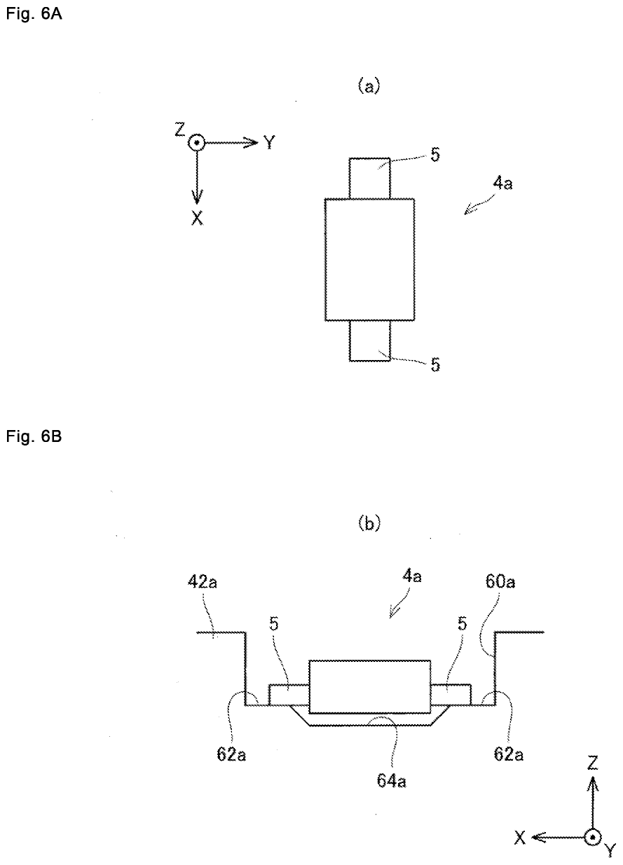

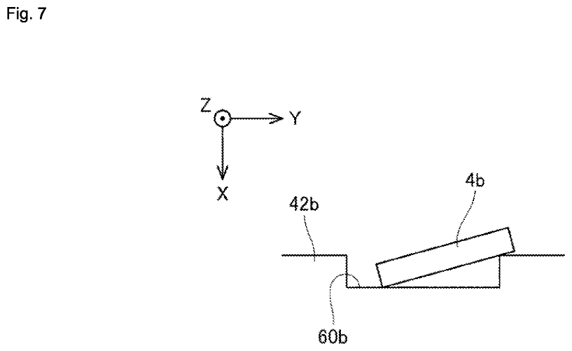

Supply condition setting section 52 sets the supply condition of tape 40 for each electronic component 4 when supplying electronic component 4 based on the shape data of electronic component 4. That is, control device 26 functions as supply condition setting section 52 by executing the program stored in storage section 50. Tape feed-out mechanism 38 feeds out tape 40 by a predetermined amount, and stops tape 40 such that electronic component 4 stops at pick-up position A (refer to FIG. 2). Depending on the type of electronic component 4, when tape 40 is fed under the same supply condition as other electronic components 4, it may deviate from a predetermined position on base tape 42 when it is stopped at pick-up position A. One of the causes of the deviation of electronic component 4 during the stoppage is the shape of electronic component 4. For example, electronic component 4a provided with leads 5 such as a 2 pin diode illustrated in FIGS. 6(a) and 6(b), thin electronic component 4b such as a ball grid array (BGA) illustrated in FIG. 7, or the like has a shape that easily deviates when it is stopped at pick-up position A. In FIG. 7, the bumps included in electronic component 4b are not illustrated.

As illustrated in FIG. 6(a), electronic component 4a in which lead 5 extends in a direction (that is, an X-direction) orthogonal to and horizontal to a conveyance direction (that is, a Y-direction) is more likely to deviate in the conveyance direction (that is, the Y-direction) in which lead 5 is not provided than in the direction in which lead 5 extends (that is, the X-direction). As described above, electronic component 4 is accommodated between base tape 42 and cover tape 44, and more specifically, is accommodated in the cavity provided in base tape 42. As illustrated in FIG. 6(b), in cavity 60a provided in base tape 42a, first portions 62a provided at positions for supporting leads 5 may be in higher positions than second portion 64a between first portions 62a. In such a case, electronic component 4a is supported only by lead 5 (that is, only a portion of lead 5 is in contact with base tape 42a), and electronic component 4a may easily deviate in a direction in which an inertial force acts, that is, in the conveyance direction (Y-direction in FIG. 6(b)) when it is stopped at pick-up position A, and protrude from cavity 60a. Therefore, when electronic component 4a is supplied, in a case where the same supply condition as tape 40 accommodating other electronic components 4 (for example, electronic component 4 without lead 5) is applied, electronic component 4a is more likely to deviate than other electronic components 4.

As illustrated in FIG. 7, in thin electronic component 4b, the dimension of cavity 60b provided in base tape 42b in a depth direction is also reduced. Therefore, when electronic component 4b is supplied, in a case where the same supply condition as tape 40 accommodating other electronic components 4 (for example, electronic components 4 other than BGA) is applied, electronic component 4b is more likely to deviate than other electronic components 4.

In addition, a magnet (not illustrated) is disposed below tape 40 in the vicinity of pick-up position A in component supply feeder 30, so that electronic component 4 having magnetism is made difficult to deviate at pick-up position A by the magnet. However, the above-described electronic components 4a and 4b may not obtain a magnetic attraction force corresponding to the mass, and may not be made difficult to deviate at pick-up position A by the magnet.

Based on the shape data of electronic component 4 stored in storage section 50, supply condition setting section 52 determines whether electronic component 4 has a specific feature that is easy to deviate (for example, whether electronic component 4 includes lead 5 extending in the X-direction, whether electronic component 4 is a thin BGA, or the like), and changes the supply condition of tape 40 accommodating electronic component 4 based on the determination result. Specifically, in a case where the specific feature is included in the shape data of electronic component 4, the supply condition of tape 40 is changed such that the speed or acceleration at the time of feeding tape 40 (that is, from the time when tape 40 starts to move to the time when tape 40 stops at pick-up position A) is reduced. Examples of the supply condition of tape 40 under which the speed or the acceleration at the time of feeding out tape 40 is reduced include a case where a deceleration time Δt at the time of stopping is reduced without changing a speed v at which tape 40 is fed, a case where the speed v at the time of feeding tape 40 is reduced without changing the deceleration time Δt at the time of stopping, and a case where both the speed v at which tape 40 is fed and the deceleration time Δt at the time of stopping are reduced.

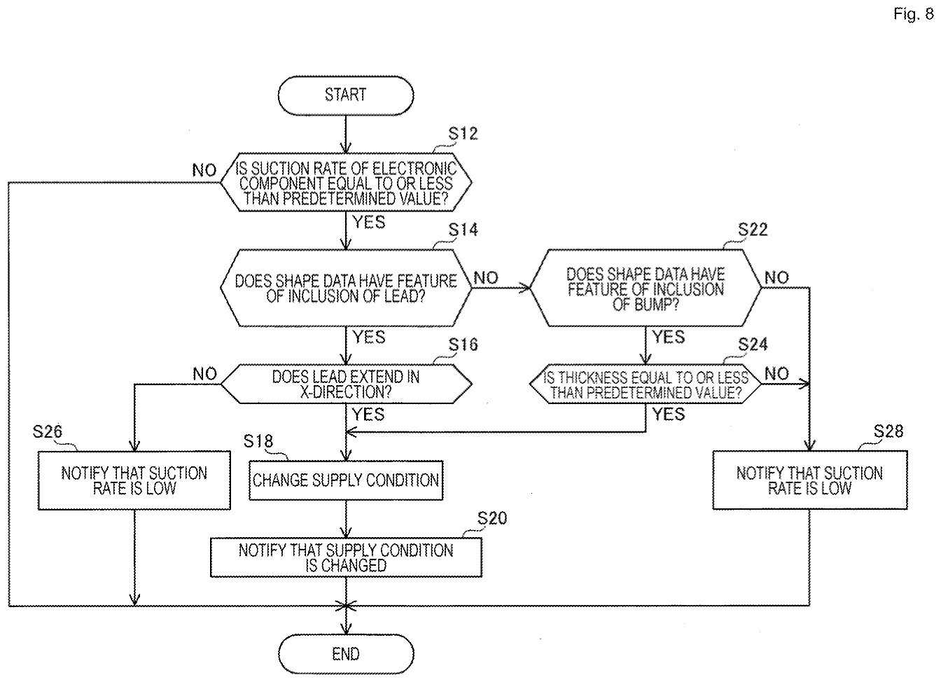

With reference to FIG. 8, a process for setting a supply condition of tape 40 when electronic component 4 is supplied by tape feed-out mechanism 38 will be described. As illustrated in FIG. 8, first, supply condition setting section 52 (that is, control device 26) determines whether the suction rate of electronic component 4 to be supplied to suction nozzle 6 is equal to or less than a predetermined value (step S12). When electronic component 4 deviates at pick-up position A, electronic component 4 cannot be picked up by suction nozzle 6. Therefore, electronic component 4 having a shape that is likely to deviate when it is stopped at pick-up position A has a lower suction rate to suction nozzle 6 than other electronic components 4. In the present embodiment, the predetermined value is set to 99.7%, but is not particularly limited. The predetermined value can be set to be lower than the suction rate to suction nozzle 6 of another electronic component 4 that does not have a shape that is likely to deviate when it is stopped at pick-up position A. In a case where the suction rate of electronic component 4 to suction nozzle 6 is larger than the predetermined value (NO in step S12), the suction rate of electronic component 4 to suction nozzle 6 is sufficiently high, so that it is unnecessary to change the supply condition of current tape 40. Therefore, supply condition setting section 52 ends the process without changing the supply condition of tape 40.

In a case where the suction rate of electronic component 4 to suction nozzle 6 is equal to or less than the predetermined value (YES in step S12), supply condition setting section 52 determines whether the shape data of electronic component 4 stored in storage section 50 has a feature of including a lead (S14). When the shape data has the feature of including the lead (YES in step S14), supply condition setting section 52 determines whether the shape data includes the feature that the lead extends in the X-direction (that is, a direction orthogonal to and horizontal to a direction to be supplied) (S16). As described above, electronic component 4a on which lead 5 extends in the X-direction easily deviates in the conveyance direction (that is, the Y-direction) when it is stopped at pick-up position A (refer to FIGS. 6(a) and 6(b)). Therefore, when the shape data includes the feature that the lead extends in the X-direction (YES in step S16), supply condition setting section 52 changes the supply condition of tape 40 (S18). Specifically, supply condition setting section 52 changes the supply condition of tape 40 such that the speed or the acceleration at the time of feeding tape 40 is reduced.

On the other hand, when the shape data does not include the feature that the lead extends in the X-direction (NO in step S16), supply condition setting section 52 determines that electronic component 4 includes the lead but is not disposed so as to easily deviate when the lead stops at pick-up position A. That is, supply condition setting section 52 determines that the suction rate of electronic component 4 to suction nozzle 6 is low because of a cause different from the cause assumed in the present embodiment (cause caused by the shape of electronic component 4). Control device 26 notifies the operator that the suction rate of electronic component 4 to suction nozzle 6 is low (S26). Specifically, control device 26 displays that the suction rate of electronic component 4 to suction nozzle 6 is low on touch panel 24. At this time, control device 26 may also notify that a cause of the low suction rate of electronic component 4 to suction nozzle 6 has not been specified (cause is unknown).

When the shape data does not have the feature of including the lead (NO in step S14), supply condition setting section 52 determines whether the shape data of electronic component 4 stored in storage section 50 includes the feature of having a bump (S22). As described above, electronic component 4b having the bump (that is, the BGA) is often thin, and easily deviates in the conveyance direction (that is, the Y-direction) when it is stopped at pick-up position A (refer to FIG. 7). Therefore, when the shape data includes the feature of having the bump (YES in step S22), supply condition setting section 52 determines whether the shape data includes the feature that the thickness of electronic component 4 is equal to or less than a predetermined value (S24). In the present embodiment, the predetermined value is 0.5 mm, but is not particularly limited. A value indicating that electronic component 4 is thin can be set, and can be appropriately selected based on the size of electronic component 4 or the like. When the thickness of electronic component 4 is equal to or less than the predetermined value (YES in step S24), supply condition setting section 52 changes the supply condition of tape 40 such that the speed or the acceleration at the time of feeding tape 40 is reduced (S18).

When the supply condition of tape 40 is changed, control device 26 notifies the operator that the supply condition of tape 40 is changed (S20). Specifically, control device 26 displays that the supply condition of tape 40 has been changed (specifically, the supply condition of tape 40 has been changed such that the speed or the acceleration at the time of feeding tape 40 is reduced) on touch panel 24. At this time, control device 26 may also notify that the supply condition of tape 40 is changed because electronic component 4 has a shape that is likely to deviate when it is stopped at pick-up position A.

On the other hand, in a case where the thickness of electronic component 4 is not equal to or less than the predetermined value (NO in step S24), supply condition setting section 52 determines that electronic component 4 is BGA, but electronic component 4 is thick enough not to easily deviate when it is stopped at pick-up position A because of the thickness of electronic component 4. In addition, when the shape data does not include the feature of having the bump (NO in step S22), supply condition setting section 52 determines that electronic component 4 is neither a shape having the lead nor a shape having the bump. That is, in any case, control device 26 determines that the suction rate of electronic component 4 to suction nozzle 6 is low because of a cause different from the cause assumed in the present embodiment (cause caused by the shape of electronic component 4). Control device 26 notifies the operator that the suction rate of electronic component 4 to suction nozzle 6 is low (S28). Since the process in step S28 is the same as the process in step S26 described above, detailed descriptions thereof will be omitted.

In the present embodiment, as examples of the shape of electronic component 4 that is likely to deviate when it is stopped at pick-up position A, a shape in which the lead extends in a direction orthogonal to and horizontal to the conveyance direction (that is, the X-direction) and a thin shape are exemplified, but the present disclosure is not limited to this. Any shape other than the above-described shape may be used as long as it is expected to easily deviate when it is stopped at pick-up position A. In addition, an example of the shape of electronic component 4 having the lead that is likely to deviate when it is stopped at pick-up position A is not limited to a shape in which the lead extends in a direction orthogonal to and horizontal to the conveyance direction (that is, the X-direction). For example, the shape may be a shape that the lead extends in the conveyance direction (that is, the Y-direction).

In addition, in the present embodiment, storage section 50 and supply condition setting section 52 are provided in control device 26 of component mounting machine 10, but are not limited to such a configuration. Storage section 50 and supply condition setting section 52 may be provided in management device 8 or component supply feeder 30. In addition, storage section 50 and supply condition setting section 52 may be provided in any of management device 8, component mounting machine 10, and component supply feeder 30, and may be provided in different devices instead of the same device.

Points of attention regarding component mounting system 1 described in the embodiment will be described. Tape feed-out mechanism 38 of the embodiment is an example of the “component feeding mechanism”, control device 26 is an example of the “control section”, suction nozzle 6 is an example of the “nozzle”, and touch panel 24 is an example of the “notification section”.

Although specific examples of the technology disclosed in the present specification have been described in detail above, they are merely examples and are not intended to limit the scope of the claims. A technology claimed in the scope of the claims includes various modifications and alterations which are made to the specific examples that have been exemplified heretofore. In addition, the technical elements described in the present specification or the drawings exhibit technical usefulness alone or in various combinations and are not limited to the combinations described in the claims at the time of filing. In addition, the technology exemplified in the present specification or the drawings simultaneously achieves multiple purposes, and has technical usefulness with achieving one purpose itself of the multiple purposes.

1. A component mounting system comprising:
a tape-type component supply feeder detachably attached to a component mounting machine for mounting an electronic component on a board, having a component feeding mechanism feeding out the electronic component to be accommodated in a tape to a supply position, and configured to supply the electronic component fed to the supply position to the component mounting machine;
a storage section configured to store shape data of the electronic component; and
a control section configured to determine a speed from a time when the electronic component is fed to the supply position to a time when the electronic component is stopped by the component feeding mechanism, based on the shape data of the electronic component.

2. The component mounting system according to claim 1, wherein the control section determines, in an electronic component to be supplied, when the shape data of the electronic component stored in the storage section includes a specific feature, a speed from a time when the electronic component is fed to the supply position to a time when the electronic component is stopped so as to be smaller than the speed from a time when another electronic component not having the specific feature is fed to the supply position to a time when the electronic component is stopped.

3. The component mounting system according to claim 2, further comprising a nozzle configured to pick up the electronic component at the supply position, wherein the control section determines, when a suction rate when the nozzle picks up the same type of electronic component multiple times is lower than a predetermined value, whether the shape data of the electronic component stored in the storage section has the specific feature.

4. The component mounting system according to claim 2, further comprising a notification section configured to notify that the control section determines to reduce the speed.

5. The component mounting system according to claim 2, wherein the specific feature is a feature in which the electronic component includes a lead extending from a main body of the electronic component when the electronic component is viewed in plan.

6. The component mounting system according to claim 2, wherein the specific feature is a feature in which a thickness of the electronic component is equal to or less than a predetermined thickness.

7. A component mounting system comprising:
a tape-type component supply feeder detachably attached to a component mounting machine for mounting an electronic component on a board, having a component feeding mechanism feeding out the electronic component to be accommodated in a tape to a supply position, and configured to supply the electronic component fed to the supply position to the component mounting machine;
a storage section configured to store shape data of the electronic component; and
a control section configured to determine an acceleration from a time when the electronic component is fed to the supply position to a time when the electronic component is stopped by the component feeding mechanism, based on the shape data of the electronic component.

8. A supply method of supplying an electronic component to a supply position from a tape-type component supply feeder that is detachably attached to a component mounting machine that mounts the electronic component on a board and feeds out the electronic component accommodated in a tape to supply the electronic component to the component mounting machine, the method comprising:
a determining step of determining a speed from a time when the electronic component is fed to the supply position to a time when the electronic component is stopped based on shape data of the electronic component to be supplied; and
a supplying step of supplying the electronic component based on the speed determined in the determining step.

9. A supply method of supplying an electronic component to a supply position from a tape-type component supply feeder that is detachably attached to a component mounting machine that mounts the electronic component on a board and feeds out the electronic component accommodated in a tape to supply the electronic component to the component mounting machine, the method comprising:
a determining step of determining an acceleration from a time when the electronic component is fed to the supply position to a time when the electronic component is stopped based on shape data of the electronic component to be supplied; and
a supplying step of supplying the electronic component based on the acceleration determined in the determining step.
